(19) United States
(12) Patent Application Publication
(10) Pub. No.: US 2018/0188626 A1
(43) Pub. Date: Jul. 5, 2018

(54) DISPLAY PANEL, METHOD OF MANUFACTURING THE SAME, AND DISPLAY USING THE SAME

(71) Applicants: HKC Corporation Limited, Shenzhen City (CN); Chongqing HKC Optoelectronics Technology Co.,ltd., Chongqing (CN)

(72) Inventor: Chungkuang Chien, Chongqing (CN)

(21) Appl. No.: 15/832,723

(22) Filed: Dec. 5, 2017

Related U.S. Application Data
(63) Continuation of application No. PCT/CN2017/078052, filed on Mar. 24, 2017.

(30) Foreign Application Priority Data
Dec. 29, 2016 (CN) 201611250653.0

(51) Int. Cl. G02F 1/1362; G02F 1/1368; H01L 27/12; H01L 21/027; G02F 1/1339

(52) U.S. Cl. CPC G02F 1/136286; G02F 1/1368; H01L 27/127; H01L 27/1288; H01L 27/1222; H01L 29/66765; H01L 27/124; G02F 1/13394; G02F 2202/02; G02F 2202/103; G02F 2001/136295; H01L 21/0274

(57) ABSTRACT

A display panel is disclosed that includes a first substrate, a second substrate, and a liquid crystal layer sandwiched between the second substrate and the first substrate. The first substrate includes a first base, a switch array layer disposed on the first base, a filter layer covering the first base and the switch array layer, and a passivation layer and a first conductive layer disposed in succession on the filter layer. The filter layer has a first through hole. The first conductive layer is coupled through the first through hole of the filter layer to the switch array layer. The first conductive layer is defined with at least one recess which may be filled with a filler. There are also disclosed a method of manufacturing the display panel and a display to which the display panel is applied.

### CROSS REFERENCE TO RELATED APPLICATIONS

This application is a continuation of PCT/CN2017/078052 filed on Mar. 24, 2017, entitled “DISPLAY PANEL, METHOD OF MANUFACTURING THE SAME, AND DISPLAY USING THE SAME”, and the entire contents of which is hereby incorporated by reference.

### BACKGROUND OF THE DISCLOSURE

### 1. Field of the Disclosure

The present disclosure relates generally to display technologies, and more particularly to a display panel, a method of manufacturing the same, and a display using the same.

### 2. Description of the Prior Art

A display panel generally includes a first substrate, a second substrate, and a liquid crystal layer sandwiched between the first substrate and the second substrate. A pixel electrode of the first substrate may be defined with a concave portion and so the pixel electrode can be coupled through concave portion to a source electrode and a drain electrode. However, when liquid crystal is injected into between the first substrate and the second substrate, the liquid crystal may flow into the concave portion, resulting in a poor diffusion of the liquid crystal, thereby affecting the quality of the display panel.

### SUMMARY OF THE DISCLOSURE

In view of the above problems, the present disclosure provides a display panel in order to solve to a certain degree the problem of poor quality of the display panel in the prior art.

To solve the above problems, the present disclosure provides a display panel that includes a first substrate, a second substrate, and a liquid crystal layer sandwiched between the second substrate and the first substrate. The first substrate may include a first base, a switch array layer disposed on the first base, a filter layer covering the first base and the switch array layer, and a passivation layer and a first conductive layer provided in succession on the surface of the filter layer. The filter layer may have a first through hole. The first conductive layer may be coupled through the first through hole of the filter layer to the switch array layer. The first conductive layer may be defined with at least one recess which may be filled with a filler.

The recess may have a depth of 1 to 2 μm, and the filler may have a height of 1 to 2 μm.

The filler may be of polyimide or polymethyl methacrylate.

The filter layer may be defined with at least one first through hole, and a part of the passivation layer may be accommodated within the first through hole. The partial passivation layer may be defined with at least one second through hole, and a part of the first conductive layer may be received within the second through hole. The first conductive layer may be coupled through the first through hole of the filter layer and the second through hole to the switch array layer, and the recess may be defined in the partial first conductive layer that is received within the second through hole.

The filter layer may include a plurality of color resist elements connected in series, and every two adjacent color resist elements may overlap.

The switch array layer may include a first metal layer disposed on the first base, an intermediate layer provided on the first metal layer and the first base, and a second metal layer disposed on the intermediate layer, the first metal layer, and the first base. The first conductive layer may be coupled to the second metal layer.

The first metal layer may be a first metal composite layer, being a molybdenum-aluminum metal composite layer, a molybdenum-aluminum alloy composite layer, a titanium-aluminum metal composite layer, or a copper-molybdenum metal composite layer.

The second metal layer may be a second metal composite layer, being a molybdenum-aluminum-molybdenum metal composite layer, a titanium-aluminum-titanium composite layer, or a copper-molybdenum metal composite layer.

The intermediate layer may include an insulating layer and an amorphous silicon layer that are disposed in succession on the surface of the first metal layer and the surface of the first base.

A protective layer may be formed between the filter layer and the second metal layer. Both the protective layer and the passivation layer may be of monosilicon mononitride or trisilicon tetranitride (also abbreviated as silicon nitride).

The second substrate may include a second base, a matrix layer disposed on the second base, and a second conductive layer provided on the second base and the matrix layer.

Both the first conductive layer and the second conductive layer may be translucent or transparent conductive metal layers.

The translucent or transparent conductive metal layer is made of indium oxide, tin oxide, zinc oxide, cadmium oxide, cadmium-indium oxide, tin-cadmium oxide, zin-tin oxide, a mixture of indium oxide and zinc oxide, or tin-doped indium trioxide.

The display panel may further include multiple spacer columns connected between the first conductive layer and the second conductive layer.

The spacer columns may be of polyimide or polymethyl methacrylate.

There is also provided a method of manufacturing a display panel, the method comprising:
providing a first base and forming a switch array layer on the first base;
forming a filter layer on the first base and the switch array layer, the filter layer being defined with a first through hole;
forming in succession a passivation layer and a first conductive layer on the filter layer, the first conductive layer being coupled through the first through hole of the filter layer to the switch array layer and being defined with a recess;
filling the recess with a filler to obtain a first substrate;
providing a second substrate and pairing the second substrate with the first substrate; and
injecting a liquid crystal into between the second substrate and the first substrate to form a liquid crystal layer.

The preparation of the filter layer may comprise:
providing a photoresist;
coating the first base and the switch array layer with the photoresist to form a photoresist film;
performing photolithography with the photoresist film to form a plurality of color resist elements, every two adjacent color resist elements overlapping and the filter layer being defined with at least one first through hole.

Filling the recess with the filler may comprise:
filling the recess with an organic solvent and coating the surface of the first conductive layer with an organic material to form an organic layer; and
performing photolithography with the organic layer to form a plurality of spacer columns and at least one filler, the plurality of spacer columns being connected between the first conductive layer and the second substrate, the recess being filled with the filler.

The preparation of the second substrate may include:
providing a second base;
disposing a matrix layer on the second base; and
plating a second conductive layer on the surface of the second base and the surface of the matrix layer.

There is further provided a display that includes the display panel. The display panel may include a first substrate, a second substrate, and a liquid crystal layer sandwiched between the second substrate and the first substrate. The first substrate may include a first base, a switch array layer disposed on the first base, a filter layer covering the first base and the switch array layer, and a passivation layer and a first conductive layer provided in succession on the surface of the filter layer. The filter layer may have a first through hole. The first conductive layer may be coupled through the first through hole of the filter layer to the switch array layer. The first conductive layer may be defined with at least one recess which may be filled with a filler.

Advantages of the present disclosure may follow: according to the present disclosure the filter layer is defined with a first through hole and the first conductive layer is coupled through the first through hole of the filter layer to the switch array layer, while the first conductive layer is provided with at least one recess which is filled with a filler. Since the recess is filled with the filler, the liquid crystal would not flow into the recess when rejected into between the first substrate and the second substrate. Therefore, the liquid crystal can be uniformly distributed between the first substrate and the second substrate, so that the resulting display panel can have a superior quality.

### BRIEF DESCRIPTION OF THE DRAWINGS

In order to more clearly illustrate the embodiments of the present disclosure or the prior art solutions, a brief description of the accompanying drawings for use in the illustration of the embodiments herein or the prior art are provided below. It is obvious that the drawings described below depict merely some embodiments of the disclosure and those of ordinary skill in the art can obtain other drawings based on the arrangements shown in these drawings without making inventive efforts.

FIG. 1 shows a schematic view of a display panel according to an embodiment of the present disclosure.

FIG. 2 shows a flowchart illustrating a method of manufacturing a display panel according to an embodiment of the present disclosure.

Description of Reference Numerals:

| Reference | |
|---|---|
| Numeral | Name |
| 100 | Display panel |
| 10 | First substrate |
| 11 | First base |
| 12 | Filler |
| 13 | Switch array layer |
| 131 | First metal layer |
| 133 | Intermediate |
| | layer |
| 135 | Second metal layer |
| 14 | Spacer column |
| 15 | Filter layer |
| 151 | First color resist |
| | element |
| 153 | Second color |
| | resist element |
| 155 | Third color resist |
| | element |
| 157 | First through hole |
| 17 | Passivation layer |
| 171 | Second through |
| | hole |
| 19 | First conductive |
| | layer |
| 191 | Recess |
| 30 | Second substrate |
| 31 | Second base |
| 33 | Matrix layer |
| 35 | Second conductive |
| | layer |

The foregoing objects, features and advantages of the present disclosure will be described in further detail with reference to the accompanying drawings.

### DETAILED DESCRIPTION

Embodiments of the present disclosure will now be described in such definite and comprehensive details with reference to the accompanying drawings of the disclosure. It is obvious that the embodiments described herein constitute merely part but not all of the embodiments of the disclosure. Therefore all other embodiments obtained by those of ordinary skill in the art based on the embodiments of the present disclosure without making inventive efforts shall all fall in the scope of the disclosure.

It should be noted that in the embodiments herein all directional indications, e.g., up, down, left, right, front, back, . . . , are only intended to illustrate the relative positional relationships or motions among various components under a certain posture or arrangement (as shown in the drawings), thus a directional indication would vary accordingly should the particular posture change.

In addition, references to “first,” “second,” and the like herein are for illustration purposes only, and are not to be construed as indicating or implying their relative importance or implicitly indicating the number of technical features involved. Thus, a feature that is defined by “first,” or “second,” and the like may include at least one such feature, either explicitly or implicitly. Furthermore, solutions of various embodiments can be combined with one another. However, any such combinations should be predicated on the achievability by those of ordinary skill in the art. Hence, any combinations of solutions should be considered to be absent nor within the claimed scope of the disclosure should such combinations end up in contradiction or unachievability.

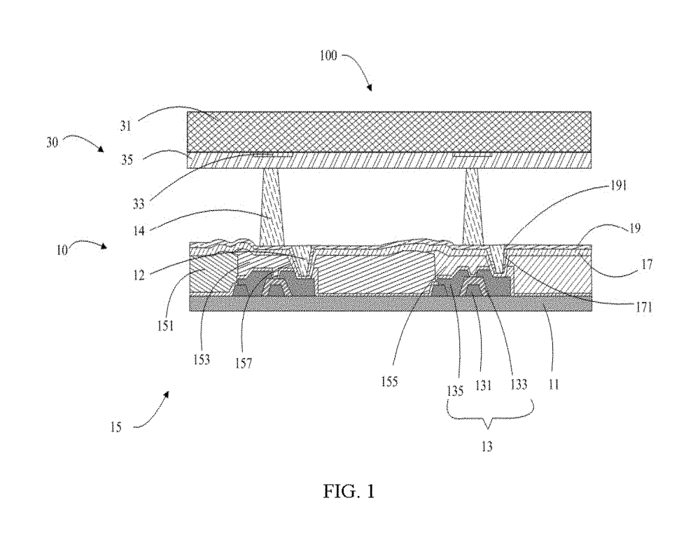

Referring to FIG. 1, there is provided a display panel 100.

The display panel 100 may include a first substrate 10, a second substrate 30, and a liquid crystal layer sandwiched between the second substrate 30 and the first substrate 10. The first substrate 10 may include a first base 11, a switch array layer 13 disposed on the first base 11, a filter layer 15 covering the first base 11 and the switch array layer 13, and a passivation layer 17 and a first conductive layer 19 disposed in succession on the surface of the filter layer 15. The filter layer 15 may have a first through hole 157. The first conductive layer 19 may be coupled through the first through hole 157 of the filter layer 15 to the switch array layer 13. The first conductive layer 19 may be defined with at least one recess 191 which may be filled with a filler 12.

In the present embodiment, the number of the recesses 191 can be, e.g., 2, in order to correspond to two switch array layers 13.

That is, the filter layer 15 may be defined with a first through hole 157, and the first conductive layer 19 may be coupled through the first through hole 157 of the filter layer 15 to the switch array layer 13. The first conductive layer 19 may be provided with at least one recess 191, inside which may be filled via a filler 12. Since the recess 191 is filled with the filler 12, the liquid crystal would not flow into the recess 191 when rejected into between the first substrate 10 and the second substrate 30. Therefore, the liquid crystal can be uniformly distributed between the first substrate 10 and the second substrate 30, thereby the resulting display panel 100 can have a superior quality.

The recess 191 may have a depth of 1 to 2 μm, and the filler 12 may have a height of 1 to 2 μm.

That is, the recess 191 may have a depth of 12 μm while the filler 12 may have a height of 1-2 μm, the recess 191 being filled with the filler 12. Furthermore, the surface of the filler 12 near the second substrate 30 may be flush with the surface of the first conductive layer 19. Therefore, when the liquid crystal is injected into between the first substrate 10 and the second substrate 30, the liquid crystal would not flow into the recess 191, because the recess 191 is filled with the filler 12 and the surface of the filler 12 near the second substrate 30 is level with the surface of the first conductive layer 19, and so the liquid crystal can be evenly distributed between the first substrate 10 and the second substrate 30, enabling the resulting display panel 100 with a superior quality.

The filler 12 may be of a polyimide material or a polymethyl methacrylate material.

In other words, the filler 12 may be made of a polyimide material or a polymethyl methacrylate material, so that the recess 191 can be sealed by the filler 12, and thus the liquid crystal can be prevented from flowing into the recess 191.

The filter layer 15 may be provided with at least one first through hole 157, and a part of the passivation layer 17 may be accommodated inside the first through hole 157. The partial passivation layer 17 may be defined with at least one second through hole 171, and a part of the first conductive layer 19 may be accommodated within the second through hole 171, where the recess 191 may be defined in the part of the first conductive layer 19 that is received in the second through hole 171.

The number of the first through holes 157, the second through holes 171, and the recesses 191 can be determined according to actual production requirements. In the present embodiment, the number of the first through holes 157, the number of the second through holes 171, and the number of the recesses 191 can all be two.

That is, a part of the passivation layer 17 may be accommodated inside the first through hole 157 of the filter layer 15, in turn a part of the first conductive layer 19 may be held inside the second through hole 171. The recess 191 may be defined in the part of the first conductive layer 19 that is received within the second through hole 171. The first through hole 157, the second through hole 171, and the recess 191 can be connected with each other, so that the first conductive layer 19 can be coupled through the first through hole 157 and the second through hole 171 to the second metal layer 135.

The filter layer 15 may include a plurality of color resist elements connected in series, and every two adjacent color resist elements may overlap.

The filter layer 15 may be a color filter, including a first color resist element 131 (red resist), a second color resist element 133 (green resist), and a third color resist element 135 (blue resist).

Among the multiple color resist elements sequentially connected according to the solution of the present disclosure, every two adjacent color resist elements may overlap, thereby providing a superior color display with the display panel 100.

The switch array layer 13 may include a first metal layer 131 disposed on the first base 11, an intermediate layer 133 provided on the first metal layer 131 and the first base 11, and a second metal layer 135 disposed on the intermediate layer and the first base 11. The first conductive layer 19 maybe coupled to the second metal layer 135.

The first metal layer 131 may form a gate, a gate line, and a common electrode.

The second metal layer 135 may form a source and a drain.

The intermediate layer 133 may include an insulating layer and an amorphous silicon layer that are disposed in succession on the surface of the first metal layer 131 and the surface of the first base 11. The insulating layer may be a silicon nitride (SiNₓ) layer or a gate-silicon nitride (G—SiNₓ) layer, x being 1 or ¾. The amorphous silicon layer may include an amorphous silicon (α-Si) layer and an N-type amorphous silicon (N+α-Si) layer deposited on the amorphous silicon layer.

That is, the switch array layer 13 may include a first metal layer 131, an intermediate layer 133, and a second metal layer 135 plated on the intermediate layer and the first base 11, so that the display panel 100 can operate properly.

The first metal layer 131 maybe a first metal composite layer, being a molybdenum-aluminum metal composite layer, a molybdenum-aluminum alloy composite layer, a titanium-aluminum metal composite layer, or a copper-molybdenum metal composite layer.

That is, the first metal layer 131 is a composite metal layer, so that the first metal layer 131 can have a superior electrical conductivity.

The second metal layer 135 maybe a second metal composite layer, being a molybdenum-aluminum-molybdenum metal composite layer, a titanium-aluminum-titanium composite layer, or a copper-molybdenum metal composite layer.

That is, the second metal layer 135 is a composite metal layer, so that the second metal layer 135 can have a superior electrical conductivity.

Further a protective layer may be formed between the filter layer 15 and the second metal layer 135. Both the protective layer and the passivation layer 17 may be of monosilicon mononitride or trisilicontetranitride (also abbreviated as silicon nitride), namely SiNₓ, with x being 1 or ¾.

Said differently, the protective layer is further formed between the filter layer 15 and the second metal layer 135 in order to protect the second metal layer 135. The passivation layer 17 can insulate the filter layer 15 from the first conductive layer 19.

The second substrate 30 may include a second base 31, a matrix layer 33 disposed on the second base 31, and a second conductive layer 35 plated on the second base 31 and the matrix layer 33.

The matrix layer 33 may be a black matrix layer.

To put it another way, the second substrate 30 may include a second base 31, a matrix layer 33, and a second conductive layer 35, so that the display panel 100 can operate properly.

Both the first conductive layer 19 and the second conductive layer 35 may be translucent or transparent conductive metal layers.

The translucent or transparent conductive metal layer is made of the materials as follows: indium oxide (In₂O₃), tin oxide (SnO₂), zinc oxide (ZnO), cadmium oxide (CdO), cadmium-indium oxide (CdIn₂O₄), cadmium-tin oxide (Cd₂SnO₄), zin-tin oxide (Zn₂SnO₄), a mixture of indium oxide and zinc oxide (In₂O₃—ZnO), or tin-doped indium oxide (In₂O₃:Sn), etc.

The first conductive layer 19 may have a depth of 0.03˜0.05 μm.

According to the solution of the present disclosure, the first conductive layer 19 and the second conductive layer 35 are both translucent or transparent conductive metal layers, so that the display panel can provide superior display effects.

The display panel 100 may further include multiple spacer columns 14 connected between the first conductive layer 19 and the second conductive layer 35.

Thus, multiple spacer columns 14 may be disposed between the first conductive layer 19 and the second conductive layer 35, so that the first conductive layer 19 and the second conductive layer 35 can form a proper gap therebetween.

Note, the display panel 100 can be enabled with an in-plane switching mode (IPS mode) or a vertical alignment mode (VA mode).

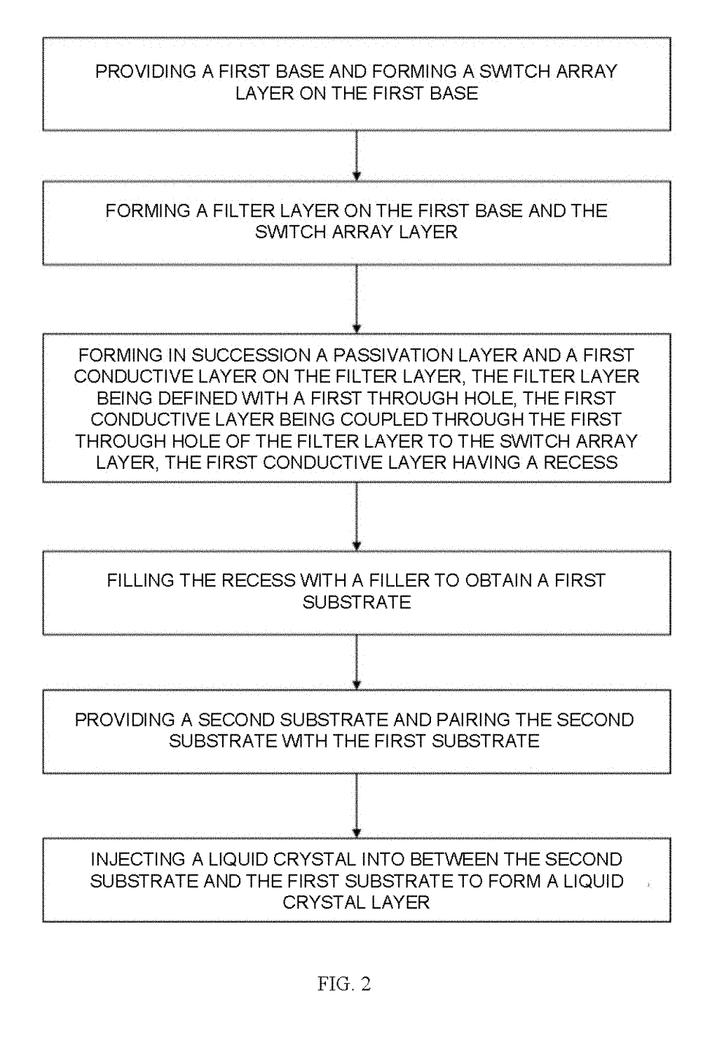

Referring now to FIG. 2, there is also provided a method of manufacturing a display panel, the method comprising:
providing a first base 11 and forming a switch array layer 13 on the first base 11;
forming a filter layer 15 on the first base 11 and the switch array layer 13;
forming in succession a passivation layer 17 and a first conductive layer 19 on the filter layer 15, the filter layer 15 being defined with a first through hole 157, the first conductive layer 19 being coupled through the first through hole 157 of the filter layer 15 to the switch array layer 13 and being defined with a recess 191;
filling the recess 191 with a filler 12 to obtain a first substrate 10;
providing a second substrate 30 and pairing the second substrate 30 with the first substrate 10; and
injecting a liquid crystal into between the second substrate 30 and the first substrate 10 to form a liquid crystal layer.

In the present embodiment, the filter layer 15 may be defined with two through holes 157, while there also are defined two recesses 191.

That is, the first conductive layer 19 may be provided with at least one recess 191, inside which maybe filled a filler 12. Since the recess 191 is filled with the filler 12, the liquid crystal would not flow into the recess 191 when rejected into between the first substrate 10 and the second substrate 30. Therefore, the liquid crystal can be uniformly distributed between the first substrate 10 and the second substrate 30, so that the resulting display panel 100 can have a superior quality.

The preparation of the switch array layer 13 may include:
plating a first metal layer 131 on the first base 11 and performing a first photolithography with the first metal layer 131 to remove a part of the first metal layer 131, in order to form a gate, a gate line, and a common electrode;
depositing in turn an insulating layer and a semiconductive silicon layer on the remained first metal layer 131 and on the first base 11;
plating a second metal layer 135 on the remained insulating layer and the remained semiconductive silicon layer; and
performing a second photolithography with the insulating layer, the semiconductive silicon layer, and the second metal layer 135, in order to remove a part of the insulating layer and semiconductive silicon layer and a part of the second metal layer 135 to form a source and a drain.

The intermediate layer 133 may include an insulating layer and an amorphous silicon layer that are coated in succession on the surface of the first metal layer 131 and the surface of the first base 11. The insulating layer may be a silicon nitride (SiNx) layer or a gate-silicon nitride (G-SiNx) layer. The amorphous silicon layer may include an amorphous silicon (α-Si) layer and an N-type amorphous silicon (N+α-Si) layer deposited on the amorphous silicon layer.

That is, the switch array layer 13 may include a first metal layer 131, an intermediate layer 133, and a second metal layer 135 plated on the intermediate layer and the first base 11, so that the display panel 100 can operate properly.

The preparation of the filter layer 15 may include:
providing a photoresist;
coating the first base 11 and the switch array layer 13 with the photoresist to form a photoresist film;
performing a third photolithography with the photoresist film to form a plurality of color resist elements, every two adjacent color resist elements overlapping and the filter layer 15 being defined with at least one first through hole 157, the partial passivation layer 17 and partial first conductive layer 19 being received within the first through hole 157.

The part of passivation layer 17 received within the first through hole 157 maybe subject to a fourth photolithography in order to form a second through hole 171. The part of the first conductive layer 19 received within the second through hole 171 may receive a fifth photolithography in order to form the recess 191.

The filter layer 15 may be a color filter, e.g., but not limited to, a first color resist element 131 (red resist), a second color resist element 133 (green resist), and a third color resist element 135 (blue resist).

Among the multiple color resist elements sequentially connected according to the solution of the present disclosure, every two adjacent color resist elements may overlap, thereby providing a superior color display with the display panel 100.

Filling the recess 191 with the filler 12 may include:
filling the recess 191 with an organic solvent and coating the surface of the first conductive layer 19 with an organic material to form an organic layer; the organic layer may be of a polyimide material or a polymethyl methacrylate material;
performing photolithography with the organic layer to form a plurality of spacer columns 14 and at least one filler 12, the plurality of spacer columns 14 being connected between the first conductive layer 19 and the second substrate 30, the recess 191 being filled with the filler 12.

The photolithography processing may include:
filling the recess 191 with an organic solvent and coating the surface of the first conductive layer 19 with an organic solvent to form an organic layer; the organic layer may be of a polyimide material or a polymethyl methacrylate material.
providing a ternary mask including a first mask, a second mask, and a third mask. The first mask may be devoid of light transmittance, i.e., the percentage light transmittance of the first mask is 0%; the percentage transmittance of the second mask is 100%; and the percentage transmittance of the third mask is 10˜90%;
placing the ternary mask on the organic layer;
performing exposure treatment with the organic layer, including: irradiating the ternary mask with ultraviolet light, where the ultraviolet light irradiated onto the first mask does not pass through the first mask so that the ultraviolet light irradiated to the first mask will not shine onto a first portion of the organic layer; the ultraviolet light irradiated to the second mask may pass through the second mask so that it may shine on a second portion of the organic layer; and the ultraviolet light irradiated to the third mask may pass in part through the third mask so that it will shine on a third portion of the organic layer;
subjecting the organic layer to a dry etching treatment to remove the unexposed organic layer, so as to form the filler 12 and the spacer column 14.

It is understood that the percent light transmittance of the third mask may lie in the range of 10˜90% which means the percent transmittance of the ultraviolet light would be in the range of 10˜90%. The third mask can correspond to the recess 191 in position, and so only a part of the ultraviolet light would be able to pass through the third mask and be irradiated onto the organic layer located on the filler 12. That is, the organic material in the filler 12 is not exposed, and so the organic layer on the filler 12 would not be completely exposed. After removal of the unexposed organic layer, the organic material in the filler 12 may not be etched and removed, thus the filler 12 can be formed in this way.

According to the solution of the present disclosure multiple spacer columns 14 may be disposed between the first conductive layer 19 and the second conductive layer 35, so that a proper gap can be formed between the first conductive layer 19 and the second conductive layer 35. Since the recess 191 is filled with the filler 12, the liquid crystal would not flow into the recess 191. Therefore, the liquid crystal can be uniformly distributed between the first substrate 10 and the second substrate 30, and so the resulting display panel 100 can have a superior quality.

The preparation of the second substrate 30 may include:
providing a second base 31;
disposing a matrix layer 33 on the second base 31; and
plating a second conductive layer 35 on the surface of the second base 31 and the surface of the matrix layer 33.

In other words, the second substrate 30 may include a second base 31, a matrix layer 33, and a second conductive layer 35, whereby the display panel 100 can operate properly.

A protective layer may be formed between the filter layer 15 and the second metal layer 135. Both the protective layer and the passivation layer 17 may be of monosilicon mononitride or trisilicon tetranitride (also abbreviated as silicon nitride), namely SiNₓ, with x being 1 or ¾.

According to the solution of the present disclosure, the protective layer is further formed between the filter layer 15 and the second metal layer 135 in order to protect the second metal layer 135. The passivation layer 17 can insulate the filter layer 15 from the first conductive layer 19.

There is further provided a display that includes the display panel 100. Because the display employs all of the solutions of the above embodiments, at least all of the advantages brought about by the solutions of the above embodiments are present here and are not to be detailed again.

It should be appreciated that the display also includes other components that perform the display function, such as a horizontal polarizer, a vertical polarizer, etc.

The foregoing description merely depicts some exemplary embodiments of the present disclosure and therefore is not intended to be limiting the scope of the disclosure. Any equivalent structural transformations made to the disclosure, or any direct or indirect applications of the disclosure on any other related fields based on the concepts of the present disclosure, shall all fall in the scope of the disclosure.

What is claimed is:

1. A display panel, comprising:
a first substrate, comprising:
a first base;
a switch array layer disposed on the first base;
a filter layer covering the first substrate and the switch array layer, the filter layer having a first through hole;
a passivation layer disposed on a surface of the filter layer; and
a first conductive layer disposed on a surface of the passivation layer, the first conductive layer being coupled through the first through hole of the filter layer to the switch array layer, the first conductive layer being defined with at least one recess, the recess being filled with a filler;
a second substrate; and
a liquid crystal layer sandwiched between the second substrate and the first substrate.

2. The display panel according to claim 1, wherein the recess has a depth of 1 μm to 2 μm, and the filler has a height of 1 μm to 2 μm.

3. The display panel according to claim 1, wherein the filler is of polyimide or polymethyl methacrylate.

4. The display panel according to claim 1, wherein the filter layer is defined with at least one of the first through hole and a part of the passivation layer is accommodated within the first through hole, where the part of the passivation layer is defined with at least one second through hole and a part of the first conductive layer is received within the second through hole, the first conductive layer being coupled through the first through hole of the filter layer and the second through hole to the switch array layer, the recess being defined in the part of the first conductive layer that is received within the second through hole.

5. The display panel according to claim 1, wherein the filter layer comprises a plurality of color resist elements connected in series, every two adjacent color resist elements overlapping.

6. The display panel according to claim 1, wherein the switch array layer comprises a first metal layer disposed on the first base, an intermediate layer disposed on the first metal layer and on the first base, and a second metal layer disposed on the intermediate layer and the first metal layer and the first base, the first conductive layer being coupled to the second metal layer.

7. The display panel according to claim 6, wherein the first metal layer is a first metal composite layer, the first metal composite layer being a molybdenum-aluminum metal composite layer, a molybdenum-aluminum alloy composite layer, a titanium-aluminum metal composite layer, or a copper-molybdenum metal composite layer.

8. The display panel according to claim 6, wherein the second metal layer is a second metal composite layer, the second metal composite layer being a molybdenum-aluminum-molybdenum metal composite layer, a titanium-aluminum-titanium composite layer, or a copper-molybdenum metal composite layer.

9. The display panel according to claim 6, wherein the intermediate layer comprises an insulating layer and an amorphous silicon layer that are disposed in succession on the first metal layer and the first base.

10. The display panel according to claim 6, further comprising a protective layer formed between the filter layer and the second metal layer, both the protective layer and the passivation layer being of monosilicon mononitride or trisilicon tetranitride.

11. The display panel according to claim 1, wherein the second substrate comprises a second base, a matrix layer disposed on the second base, and a second conductive layer disposed on the second base and on the matrix layer.

12. The display panel according to claim 11, wherein both the first conductive layer and the second conductive layer are translucent or transparent conductive metal layers.

13. The display panel according to claim 12, wherein the translucent or transparent conductive metal layer is made of indium oxide, tin oxide, zinc oxide, cadmium oxide, cadmium-indium oxide, cadmium-tin oxide, zinc-tin oxide, a mixture of indium oxide and zinc oxide, or tin-doped indium oxide.

14. The display panel according to claim 11, further comprising a plurality of spacer columns connected between the first conductive layer and the second conductive layer.

15. The display panel according to claim 14, wherein the spacer columns are of polyimide or polymethyl methacrylate.

16. A method of manufacturing a display panel, the method comprising:
providing a first base and forming a switch array layer on the first base;
forming a filter layer on the first base and on the switch array layer, the filter layer being defined with a first through hole;
forming in succession a passivation layer and a first conductive layer on the filter layer, the first conductive layer being coupled through the first through hole of the filter layer to the switch array layer and being defined with a recess;
filling the recess with a filler to obtain a first substrate;
providing a second substrate and pairing the second substrate with the first substrate; and
injecting a liquid crystal into between the second substrate and the first substrate to form a liquid crystal layer.

17. The method according to claim 16, wherein preparation of the filter layer comprising:
providing a photoresist;
coating the first base and the switch array layer with the photoresist to form a photoresist film; and
performing photolithography with the photoresist film to form a plurality of color resist elements, every two adjacent color resist elements overlapping and the filter layer being defined with at least one of the first through hole.

18. The method according to claim 16, wherein filling the recess with the filler comprising:
filling the recess with an organic solvent and coating a surface of the first conductive layer with an organic material to form an organic layer; and
performing photolithography with the organic layer to form a plurality of spacer columns and at least one filler, the plurality of spacer columns being connected between the first conductive layer and the second substrate, the recess being filled with the filler.

19. The method according to claim 16, wherein preparation of the second substrate comprising:
providing a second base;
disposing a matrix layer on the second base; and
plating a second conductive layer on a surface of the second base and a surface of the matrix layer.

20. A display comprising a display panel, the display panel comprising:
a first substrate, comprising:
a first base;
a switch array layer disposed on the first base;
a filter layer covering the first substrate and the switch array layer, the filter layer having a first through hole;
a passivation layer provided on a surface of the filter layer; and
a first conductive layer provided on a surface of the passivation layer, the first conductive layer being coupled through the first through hole of the filter layer to the switch array layer, the first conductive layer being defined with at least one recess, the recess being filled with a filler;
a second substrate; and
a liquid crystal layer sandwiched between the second substrate and the first substrate.
